(19) United States
(12) Patent Application Publication
(10) Pub. No.: US 2015/0255482 A1
(43) Pub. Date: Sep. 10, 2015

(54) SEMICONDUCTOR STORAGE DEVICE AND MANUFACTURING METHOD THEREOF

(71) Applicant: Kabushiki Kaisha Toshiba, Minato-ku (JP)

(72) Inventors: Kensei TAKAHASHI, Kuwana-shi (JP); Kazuhiro Matsuo, Yokkaichi-shi (JP); Fumiki Aiso, Kuwana-shi (JP); Masao Shingu, Yokkaichi-shi (JP); Masayuki Tanaka, Yokkaichi-shi (JP)

(73) Assignee: Kabushiki Kaisha Toshiba, Minato-ku (JP)

(21) Appl. No.: 14/310,239

(22) Filed: Jun. 20, 2014

Related U.S. Application Data
(60) Provisional application No. 61/949,003, filed on Mar. 6, 2014.

(51) Int. Cl. H01L 27/115

(52) U.S. Cl. CPC H01L 27/11582

(57) ABSTRACT

A semiconductor storage device according to an embodiment includes a semiconductor layer. A tunnel dielectric film is formed on the semiconductor layer. A charge accumulation layer is formed on the tunnel dielectric film. A block film is formed on the charge accumulation layer. A control gate is formed on the block film. The block film includes a metal oxide film containing nitrogen in a concentration range equal to or lower than 5×10²¹ atoms/cm³ and consisting mainly of aluminum.

### CROSS REFERENCE TO RELATED APPLICATIONS

This application is based upon and claims the benefit of priority from the prior US Provisional Patent Application No. 61/949,003, filed on Mar. 6, 2014, the entire contents of which are incorporated herein by reference.

### FIELD

The embodiments of the present invention relate to a semiconductor device and a manufacturing method thereof.

### BACKGROUND

A three-dimensional stereoscopic memory cell array has been developed to increase the storage capacity of a semiconductor storage device such as a NAND flash memory. Also in the stereoscopic memory cell array, the physical film thickness of a block film between a charge accumulation layer and a control gate needs to be reduced to downscale memory cells.

However, in a case where the film thickness of the block film is small, charges that leak from the control gate to the charge accumulation layer during data erase increase when the number of times of W (Write)/E (Erase) increases. That is, the resistance (endurance property) of the block film is likely to be degraded.

Accordingly, there has been a demand for maintaining or improving the resistance of the block film even when the film thickness of the block film is small.

### BRIEF DESCRIPTION OF THE DRAWINGS

FIG. 1 shows an example of a configuration of a semiconductor storage device according to the present embodiment;

FIG. 2 is a cross-sectional perspective view showing an example of a configuration of the memory cell MC according to the first embodiment;

FIG. 3 is a cross-sectional view showing an example of a structure from the semiconductor pillar 10 to the control gate CG;

FIG. 4 is a graph showing the quantities of trapped charge in the block film 40;

FIG. 5 is a graph showing leak currents of the block film 40;

FIG. 6 is a graph showing the concentration of nitrogen contained in the metal oxide film 44 and the quantity of trapped charges;

FIG. 7 is a flowchart showing an example of a manufacturing method of a semiconductor storage device according to the present embodiment;

FIG. 8 is a flowchart showing an example of the formation process of the metal oxide film 44;

FIG. 9 is a composition diagram showing a configuration of an aluminum source containing an amino group or amidinate; and

FIG. 10 is a graph showing relations between the nitrogen concentration of the metal oxide film 44 and the film formation temperature in the ALD process at Steps S31 to S34.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a substrate or a Si column is assumed as “an upper direction”. Therefore, the term “upper direction” or “lower direction” occasionally differs from an upper direction or a lower direction based on a gravitational acceleration direction.

A semiconductor storage device according to an embodiment includes a semiconductor layer. A tunnel dielectric film is formed on the semiconductor layer. A charge accumulation layer is formed on the tunnel dielectric film. A block film is formed on the charge accumulation layer. A control gate is formed on the block film. The block film includes a metal oxide film containing nitrogen in a concentration range equal to or lower than 5×10²¹ atoms/cm³ and consisting mainly of aluminum.

A NAND flash memory having a three-dimensional structure as an example of a semiconductor storage device according to an embodiment is explained below. However, the present embodiment can be also applied to a NAND flash memory having a two-dimensional structure. The present embodiment is not limited to a NAND flash memory and can be also applied to other semiconductor storage devices.

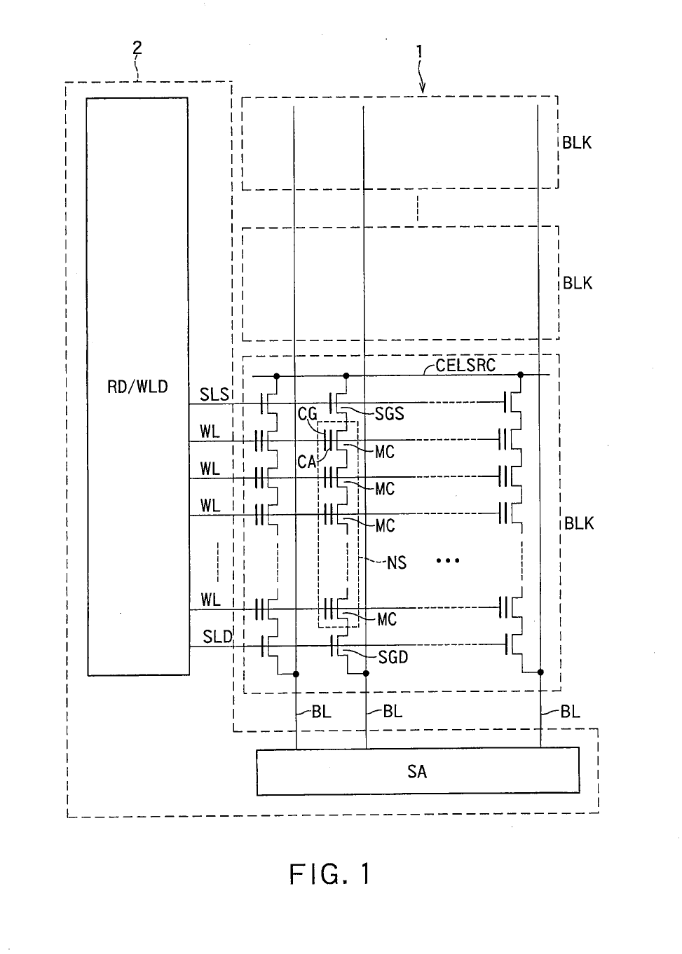

FIG. 1 shows an example of a configuration of a semiconductor storage device according to the present embodiment. The semiconductor storage device is, for example, a NAND flash memory (hereinafter, also simply “memory”). The memory includes a memory area 1 in which a plurality of memory cells MC are arranged stereoscopically and three-dimensionally, and a peripheral circuit area 2 that controls the memory area 1. For convenience sake, the memory area 1 is shown in a planar shape in FIG. 1.

The memory area 1 has a plurality of blocks BLK and each of the blocks BLK has a plurality of NAND strings NS. The block BLK is a unit of data erase. Each of the NAND strings NS has a plurality of memory cells MC connected in series. Memory cells MC on two ends of each of the NAND strings NS are connected to select gate transistors SGD and SGS, respectively. Memory cells MC on one end of the memory area 1 are connected to bit lines BL via the select gate transistors SGD, respectively, and memory cells MC on the other end of the memory area 1 are connected to a cell source CELSRC via the select gate transistors SGS, respectively.

Each of word lines WL is connected to control gates CG of memory cells MC arrayed in a row direction. Select gate lines SLD and SLS are connected to gates of the select gate transistors SGD and SGS, respectively. The word lines WL and the select gate lines SLS and SLD are driven by a row decoder RD and a word line driver WLD.

Each of the bit lines BL is connected to a plurality of NAND strings NS via the corresponding select gate transistors SGD, respectively. The bit lines BL are connected to a sense amplifier circuit SA. A plurality of memory cells MC connected to one word line WL constitute a page serving as a unit of collective data read and data write.

When the select gate lines SLS and SLD drive the select gate transistors SGS and SGD, each of the NAND strings NS is connected between the corresponding bit line BL and the cell source CELSRC. When the word line driver WLD drives a non-selected word line WL, non-selected memory cells MC are turned on. Accordingly, the sense amplifier circuit SA can apply a voltage to the selected memory cells MC via the corresponding bit lines BL. This enables the sense amplifier circuit SA to detect data in the selected memory cells MC or to write data in the selected memory cells MC. Each of the memory cells MC has a threshold voltage depending on the quantity of charges (the quantity of electrons, for example) accumulated in a charge accumulation layer CA. The sense amplifier circuit SA detects differences in the threshold voltages of the memory cells MC and determines logic of data.

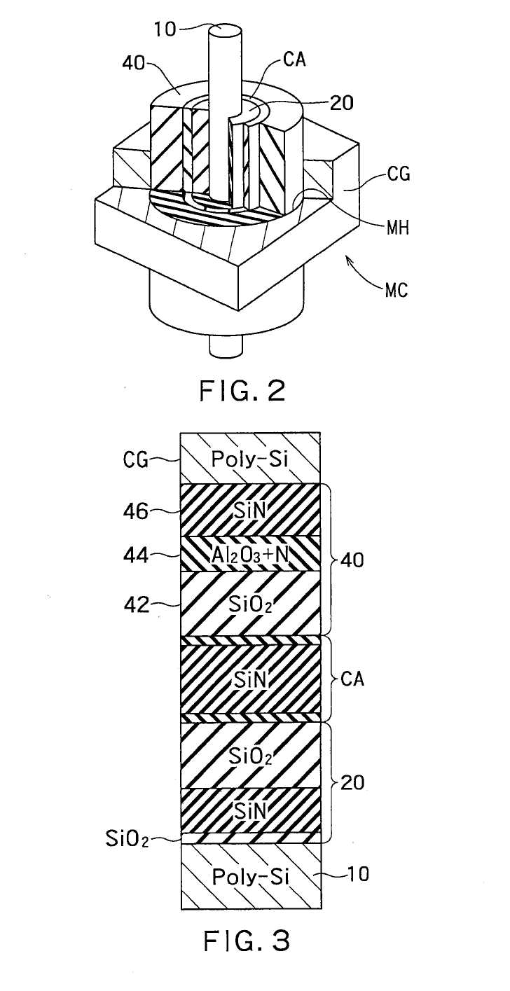

FIG. 2 is a cross-sectional perspective view showing an example of a configuration of the memory cell MC according to the first embodiment. The memory cell MC includes a semiconductor pillar 10, a tunnel dielectric film 20, the charge accumulation layer CA, a block film 40, and a control gate CG.

The semiconductor pillar 10 serving as a semiconductor layer extends, for example, in a direction substantially vertical to a surface of a substrate (not shown) and is formed of a conductive material such as doped polysilicon. The semiconductor pillar 10 is formed cylindrically and is provided to pass through the center of the memory cell MC.

The tunnel dielectric film 20 is provided on a side surface of the semiconductor pillar 10 (around the semiconductor pillar 10). The tunnel dielectric film 20 is formed of an insulating film such as a silicon dioxide film or a silicon nitride film. The tunnel dielectric film 20 can be a multilayered film including insulating films such as a silicon dioxide film and a silicon nitride film (an ONO film (a SiO—SiN—SiO film), for example).

The charge accumulation layer CA is provided on the tunnel dielectric film 20. That is, the charge accumulation layer CA is provided over the side surface of the semiconductor pillar 10 (around the semiconductor pillar 10) with the tunnel dielectric film 20 interposed therebetween. The charge accumulation layer CA is formed of a material such as doped polysilicon or a silicon nitride film.

The charge accumulation layer CA accumulates therein charges (electrons, for example) from the substrate 10 via the tunnel dielectric film 20 or emits charges to the substrate 10 via the tunnel dielectric film 20. Accordingly, the threshold voltage of the memory cell MC changes and thus the memory cell MC can store therein logical data.

The block film 40 is provided on the charge accumulation layer CA. That is, the block film 40 is provided over the side surface of the semiconductor pillar 10 (around the semiconductor pillar 10) with the tunnel dielectric film 20 and the charge accumulation layer CA interposed therebetween. The block film 40 is formed of, for example, a metal oxide film. The block film 40 can be a multilayered film including a silicon dioxide film, a silicon nitride film, or a silicon oxynitride film as well as the metal oxide film. The block film 40 is explained in more detail below with reference to FIG. 3.

The control gate CG is provided on the block film 40. That is, the control gate CG is provide over the side surface of the semiconductor pillar 10 with the tunnel dielectric film 20, the charge accumulation layer CA, and the block film 40 interposed therebetween. The control gate CG is formed of a conductive material such as doped polysilicon, tungsten, or a tungsten nitride film.

FIG. 3 is a cross-sectional view showing an example of a structure from the semiconductor pillar 10 to the control gate CG. The memory according to the present embodiment can have a so-called MONOS (Metal-Oxide-Nitride-Oxide-Semiconductor) structure.

The tunnel dielectric film 20 is, for example, an ONO film provided on the semiconductor pillar 10. The charge accumulation layer CA is a silicon nitride film provided on the tunnel dielectric film 20. A metal oxide film such as an aluminum oxide film (Al₂O₃) can be formed on the upper and bottom surfaces (both sides) of the silicon nitride film of the charge accumulation layer CA.

The block film 40 includes a silicon dioxide film 42 provided on the charge accumulation layer CA, a metal oxide film 44 provided on the silicon dioxide film 42, and a silicon nitride film 46 provided on the metal oxide film 44. The block film 40 can include a high-permittivity film having a relative permittivity that is higher than that of the silicon dioxide film (HfO₂, for example) instead of or in addition to the silicon dioxide film 42 and the silicon nitride film 44.

In this case, the metal oxide film 44 is an oxide film consisting mainly of aluminum that has a nitrogen concentration equal to or lower than approximately 5×10²¹ atoms/cm³. More preferably, the metal oxide film 44 is an oxide film consisting mainly of aluminum that has a nitrogen concentration between approximately 4×10²¹ atoms/cm³ and approximately 5×10²¹ atoms/cm³. For example, the metal oxide film 44 is an aluminum oxide film (Al₂O₃) containing nitrogen in the concentration range described above.

Addition of nitrogen to the metal oxide film 44 in the block film 40 enables trapping of charges by the metal oxide film 44. Accordingly, tunneling (back tunneling) of charges from the control gate CG to the charge accumulation layer CA during data erase can be suppressed. Furthermore, the block film 40 can reduce a leak current between the control gate CG and the charge accumulation layer CA.

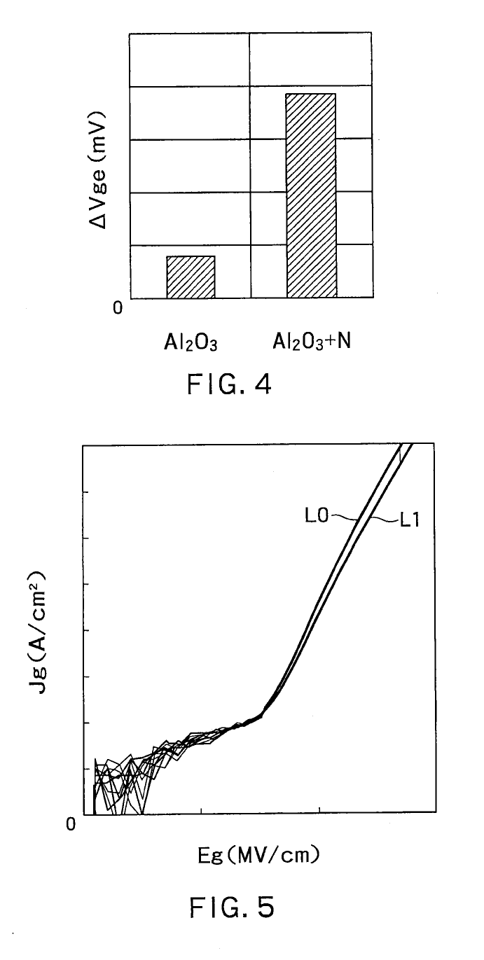

FIG. 4 is a graph showing the quantities of trapped charge in the block film 40. FIG. 5 is a graph showing leak currents of the block film 40. FIGS. 4 and 5 indicate results of comparisons between an aluminum oxide film containing no nitrogen and an aluminum oxide film containing nitrogen. In FIG. 5, L0 denotes a leak current Jg of the aluminum oxide film containing no nitrogen and L1 denotes a leak current Jg of the aluminum oxide film containing nitrogen.

As shown in FIG. 4, the quantity ΔVge of trapped charges in the aluminum oxide film containing nitrogen is larger than that of the aluminum oxide film containing no nitrogen.

As shown in FIG. 5, the leak current Jg of the aluminum oxide film containing nitrogen is smaller than that of the aluminum oxide film containing no nitrogen.

As described above, according to the present embodiment, because the metal oxide film 44 has the aluminum oxide film containing nitrogen, the block film 40 can suppress the leak current between the control gate CG and the charge accumulation layer CA and also can increase the quantity of trapped charges. Increase in the quantity of trapped charges leads to suppression in back tunneling (the leak current) during data erase. Furthermore, because the metal oxide film 44 has the aluminum oxide film containing nitrogen, the electric field is relaxed and the back tunneling (the leak current) during data erase is suppressed. That is, according to the present embodiment, the resistance of the block film 40 in a data erase operation and the like can be maintained or improved.

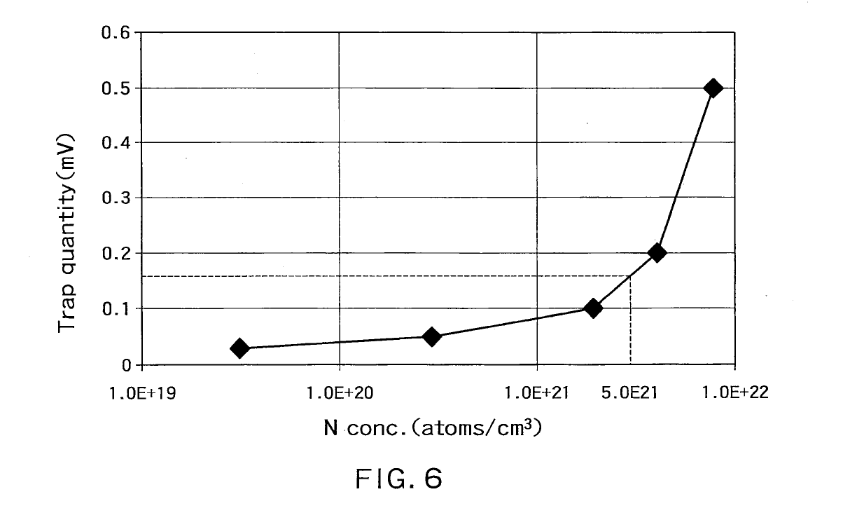

Meanwhile, if the concentration of nitrogen contained in the metal oxide film 44 is too high, the quantity of trapped charges correspondingly increases. If the quantity of trapped charges is too large, horizontal detrapping to an adjacent memory cell MC may occur. That is, charges trapped in the metal oxide film 44 may be dropped out to the metal oxide film 44 or the charge accumulation film CA in an adjacent memory cell MC. Therefore, nitrogen contained in the metal oxide film 44 has an appropriate concentration range as explained with reference to FIG. 6.

FIG. 6 is a graph showing the concentration of nitrogen contained in the metal oxide film 44 and the quantity of trapped charges. The vertical axis represents the quantity of charges trapped in the metal oxide film 44. More specifically, the vertical axis represents the amount of change in a flat band voltage occurring due to charge trapping. The horizontal axis represents the concentration of nitrogen contained in the metal oxide film 44.

As shown in FIG. 6, when the concentration of nitrogen contained in the metal oxide film 44 exceeds approximately 5×10²¹ atoms/cm³, the quantity of trapped charges in the metal oxide film 44 increases sharply. When the quantity of trapped charges exceeds approximately 0.15 mV, a risk of charges dropping out to the metal oxide film 44 or the charge accumulation layer CA in an adjacent memory cell MC increases. Therefore, it is preferable that the nitrogen concentration in the metal oxide film 44 be equal to or lower than approximately 5×10²¹ atoms/cm³.

Although not shown in FIG. 6, when the nitrogen concentration in the metal oxide film 44 is equal to or lower than approximately 4×10¹⁹ atoms/cm³, the field relaxation effect decreases and thus the effect of suppressing back tunneling shown in FIG. 5 is not expected. Therefore, it is preferable that the nitrogen concentration in the metal oxide film 44 be approximately 4×10¹⁹ atoms/cm³ to approximately 5×10²¹ atoms/cm³.

As described above, according to the present embodiment, addition of nitrogen in the metal oxide film 44 enables the metal oxide film 44 to trap charges. Accordingly, tunneling (back tunneling) of charges from the control gate CG to the charge accumulation layer CA during data erase can be suppressed. Furthermore, the block 40 can reduce the leak current and the quantity of detrapped charges between the control gate CG and the charge accumulation layer CA.

The metal oxide film 44 can be a multilayered film including an aluminum oxide film containing nitrogen and another metal oxide film containing no nitrogen. For example, the metal oxide film 44 can be a multilayered film including AlO (AlO containing no nitrogen) and AlO+N (AlO containing nitrogen) or a multilayered film including AlO, AlO+N (AlO containing nitrogen), and AlO. The embodiment described above can be applied to the memory area 1 in a planar shape in which the memory cells MC are arranged two-dimensionally.

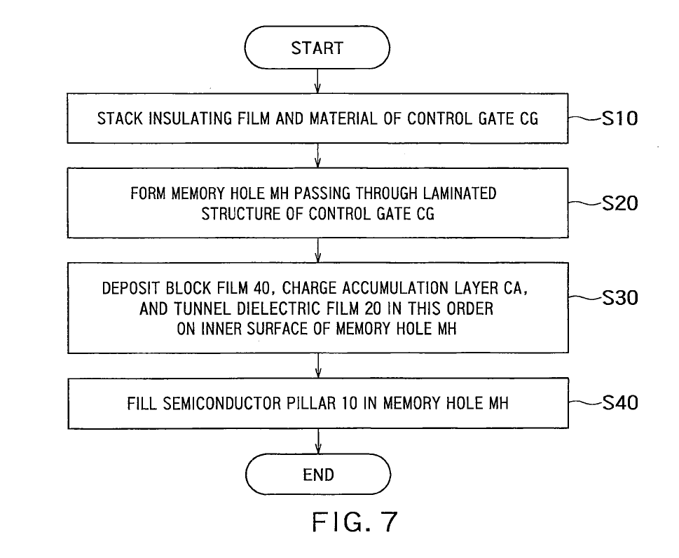

FIG. 7 is a flowchart showing an example of a manufacturing method of a semiconductor storage device according to the present embodiment. For example, a peripheral circuits and the like (not shown) and an interlayer dielectric film are first formed on a substrate. An insulating film and a desired number of materials of the control gates CG are stacked on the interlayer dielectric film (S10). In this way, the control gates CG in plural layers are formed.

Next, memory holes MH (see FIG. 2) that pass through laminated structures of the control gates CG are formed using a lithographic technique and an etching technique (S20).

Next, the block film 40, the charge accumulation layer CA, and the tunnel dielectric film 20 are deposited in this order on inner surfaces of the memory holes MH (S30). The semiconductor pillars 10 are then filled in the memory holes MH, respectively (S40). In this way, the structure shown in FIG. 2 is obtained. An interlayer dielectric film, contact plugs, wires, and the like (not shown) are thereafter formed, so that the memory according to the present embodiment is completed.

A process of forming the metal oxide film 44 in the block film 40 is explained in more detail.

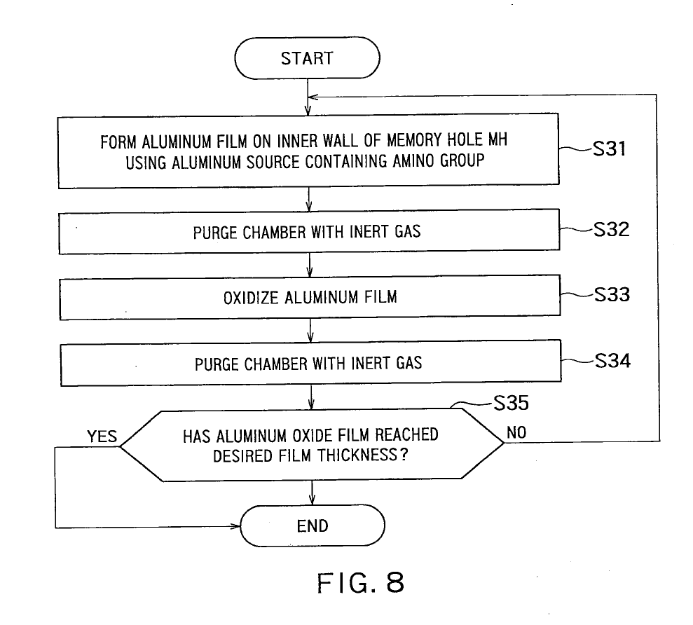

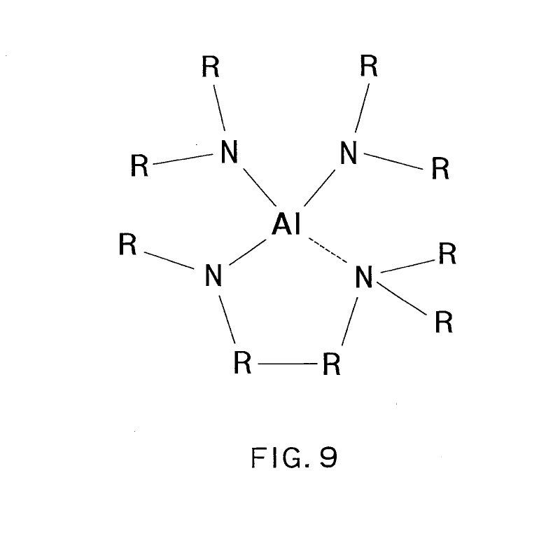

FIG. 8 is a flowchart showing an example of the formation process of the metal oxide film 44. The metal oxide film 44 is formed of, for example, an aluminum source containing an amino group or amidinate by an ALD (Atomic Layer Deposition) method. FIG. 9 is a composition diagram showing a configuration of an aluminum source containing an amino group or amidinate. The aluminum source containing an amino group is an aluminum source containing an amino group or amidinate shown in FIG. 9. R in FIG. 9 denotes an alkyl group (CH₂ or C₂H₅, for example). That is, a functional group containing N and R represents an amino group or amidinate (NH₂, NHCH₃, or NCH₂CH₃, for example). The aluminum source containing such an amino group or amidinate already contains nitrogen as a source for forming an aluminum film. Accordingly, without the need of a process to introduce nitrogen in an aluminum film or an aluminum oxide film, nitrogen can be contained in the aluminum oxide film.

As shown in FIG. 8, an aluminum film is formed at the atomic level on the inner walls of the memory holes MH (the inner wall surfaces of the control gates CG) using an aluminum source containing an amino group or amidinate (S31).

A chamber of an ALD film-formation apparatus is purged with inert gas (S32) and then the aluminum film is oxidized using an oxidant (S33). The oxidant is, for example, any of O₂, O₃, H₂O, and an oxygen radical. O₃ and the oxygen radical are easily deactivated. Uniform oxidation is difficult to realize with H₂O. Therefore, it can be said that it is preferable to use O₂ as the oxidant. At Step S33, the aluminum film is oxidized to form an aluminum oxide film at the atomic level.

The chamber of the ALD film-formation apparatus is further purged with an inert gas (S34) and then the processes at Steps S31 to S33 are performed again (NO at S35). By repeatedly performing the processes at Steps S31 to S34, the aluminum oxide film is gradually formed on the inner surfaces of the memory holes MH with respect to each atomic level. At that time, nitrogen contained in the amino group or amidinate remains in the aluminum oxide film so that the metal oxide film 44 becomes an aluminum oxide film containing nitrogen. That is, by forming the aluminum oxide film using the aluminum source containing an amino group or amidinate, nitrogen can be contained in the aluminum oxide film without passing a process of introducing nitrogen purposely. When the aluminum oxide film has reached a desired film thickness (YES at S35), the formation process of the metal oxide film 44 is ended.

The nitrogen concentration of the metal oxide film 44 is controlled to a range from approximately 5×10¹⁸ atoms/cm³ to 2×10²² atoms/cm³. The nitrogen concentration can be controlled by adjusting a film formation temperature at Step S31.

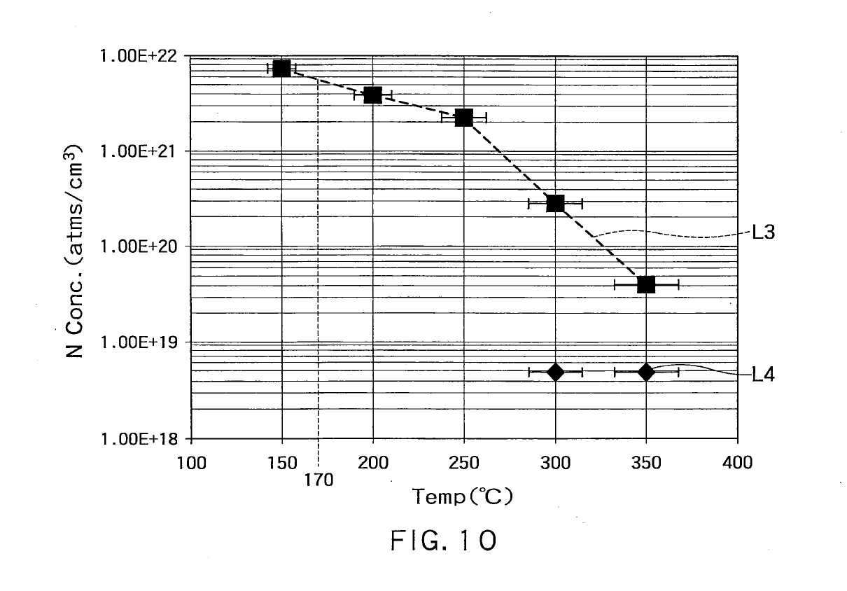

FIG. 10 is a graph showing relations between the nitrogen concentration of the metal oxide film 44 and the film formation temperature in the ALD process at Steps S31 to S34.

The graph in FIG. 10 indicates that the film formation at Step S31 is preferably performed at a temperature from approximately 170° C. to approximately 350° C. This enables the concentration of nitrogen contained in the metal oxide film 44 to be controlled in the range from approximately 5×10¹⁸ atoms/cm³ to approximately 2×10²² atoms/cm³.

According to the present embodiment, the aluminum oxide film is formed using an aluminum source containing an amino group or amidinate at the time of formation of the metal oxide film 44 of the block film 40. Accordingly, without performing the process of introducing nitrogen purposely, the aluminum oxide film containing nitrogen can be formed by the ALD method or a CVD (Chemical Vapor Deposition) method. Because the formation process of the metal oxide film 44 according to the present embodiment does not require the process of introducing nitrogen, the process is relatively simple and is completed in a short time.

For example, when the metal oxide film 44 is formed of TMA (trimethylaluminum) (L4 in FIG. 10), an aluminum film is first formed of TMA. The aluminum film is then nitrided using NH₃. The aluminum film is then oxidized to obtain an aluminum oxide film. When the aluminum oxide film containing nitrogen is formed of TMA in this way, a process (a nitridation process) of introducing nitrogen into the aluminum film is required. In the ALD method using TMA, the formation process, the nitridation process, and the oxidization process for the aluminum film are repeatedly performed. Therefore, addition of the nitridation process greatly increases the formation time of the aluminum oxide film. Furthermore, the aluminum film is difficult to nitride and a considerable time is required to introduce nitrogen in the concentration range described above into the aluminum film. Furthermore, because TMA does not contain an amino group or amidinate (nitrogen), the nitrogen concentration cannot be controlled using the formation temperature of the metal oxide film 44.

On the other hand, when an aluminum source containing an amino group or amidinate is used (L3 in FIG. 10), the formation time of the metal oxide film 44 can be reduced to about half of that in a case where TMA is used. As described above, according to the present embodiment, the block film 40 (the metal oxide film 44) can be formed easily and in a short time. As a result, the productivity of the memory is increased. Furthermore, according to the present embodiment, because a formation source of the aluminum film contains an amino group or amidinate (nitrogen), the nitrogen concentration can be controlled using the formation temperature of the metal oxide film 44.

In the embodiment described above, the metal oxide film 44 is formed by the ALD method. However, the metal oxide film 44 can be formed by the CVD method.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a semiconductor layer;
a tunnel dielectric film on the semiconductor layer;
a charge accumulation layer on the tunnel dielectric film;
a block film on the charge accumulation layer; and
a control gate on the block film, wherein the block film includes a metal oxide film containing nitrogen in a concentration equal to or lower than 5×10²¹ atoms/cm³ and consisting mainly of aluminum.

2. The device of claim 1, wherein the block film includes a metal oxide film containing nitrogen in a concentration from approximately 4×10¹⁹ atoms/cm³ and approximately 5×10²¹ atoms/cm³ and consisting mainly of aluminum.

3. The device of claim 1, wherein the block film is a multilayered film including the metal oxide film and at least one of a silicon dioxide film, a silicon nitride film, and a high-permittivity film having a relative permittivity that is higher than that of the silicon dioxide film.

4. The device of claim 1, wherein
the block film is a multilayered film including:
a silicon dioxide film on the charge accumulation layer,
the metal oxide film on the silicon dioxide film, and
a silicon nitride film on the metal oxide film.

5. The device of claim 1, wherein the metal oxide film is an aluminum oxide film (Al₂O₃) containing nitrogen in the concentration range.

6. The device of claim 1, wherein
the semiconductor layer is a semiconductor pillar arranged in a substantially vertical direction to a surface of the substrate,
the tunnel dielectric film is arranged on a side surface of the semiconductor pillar,
the charge accumulation layer is provided on the side surface of the semiconductor pillar with the tunnel dielectric film interposed therebetween,
the block film is provided on the side surface of the semiconductor pillar with the tunnel dielectric film and the charge accumulation layer interposed therebetween, and
the control gate is provided on the side surface of the semiconductor pillar with the tunnel dielectric film, the charge accumulation layer, and the block film interposed therebetween.

7. The device of claim 2, wherein
the semiconductor layer is a semiconductor pillar arranged in a substantially vertical direction to a surface of the substrate,
the tunnel dielectric film is provided on a side surface of the semiconductor pillar,
the charge accumulation layer is arranged above the side surface of the semiconductor pillar with the tunnel dielectric film interposed therebetween,
the block film is provided on the side surface of the semiconductor pillar with the tunnel dielectric film and the charge accumulation layer interposed therebetween, and
the control gate is provided on the side surface of the semiconductor pillar with the tunnel dielectric film, the charge accumulation layer, and the block film interposed therebetween.

8. The device of claim 3, wherein
the semiconductor layer is a semiconductor pillar arranged in a substantially vertical direction to a surface of the substrate,
the tunnel dielectric film is provided on a side surface of the semiconductor pillar,
the charge accumulation layer is provided on the side surface of the semiconductor pillar with the tunnel dielectric film interposed therebetween,
the block film is provided on the side surface of the semiconductor pillar with the tunnel dielectric film and the charge accumulation layer interposed therebetween, and
the control gate is provided on the side surface of the semiconductor pillar with the tunnel dielectric film, the charge accumulation layer, and the block film interposed therebetween.

9. The device of claim 4, wherein
the semiconductor layer is a semiconductor pillar arranged in a substantially vertical direction to a surface of the substrate,
the tunnel dielectric film is provided on a side surface of the semiconductor pillar,
the charge accumulation layer is provided on the side surface of the semiconductor pillar with the tunnel dielectric film interposed therebetween,
the block film is provided on the side surface of the semiconductor pillar with the tunnel dielectric film and the charge accumulation layer interposed therebetween, and
the control gate is provided on the side surface of the semiconductor pillar with the tunnel dielectric film, the charge accumulation layer, and the block film interposed therebetween.

10. A manufacturing method of a semiconductor storage device, the method comprising:
stacking a plurality of material layers of a control gate and a plurality of insulating films above a substrate;
forming a memory hole penetrating through the material layers of the control gate and the insulating films;
depositing a block film, a charge accumulation layer, and a tunnel dielectric film in this order on an inner surface of the memory hole; and
further filling a semiconductor material in the memory hole in order to form a semiconductor pillar, wherein
the block film includes a metal oxide film containing nitrogen in a concentration equal to or lower than 5×10²¹ atoms/cm³ and consisting mainly of aluminum.

11. The method of claim 10, wherein the block film includes a metal oxide film containing nitrogen in a concentration from approximately 4×10¹⁹ atoms/cm³ and approximately 5×10²¹ atoms/cm³ and consisting mainly of aluminum.

12. The method of claim 10, wherein the metal oxide film is formed of an aluminum source containing an amino group or amidinate.

13. The method of claim 10, wherein
formation of the metal oxide film comprises:
a first stage of forming an aluminum film using an aluminum source containing an amino group or amidinate; and
a second stage of oxidizing the aluminum film with an oxidant.

14. The method of claim 13, wherein the metal oxide film is formed by repeating the first and second stages.

15. The method of claim 13, wherein the oxidant is any of O₂, O₃, H₂O, and an oxygen radical.

16. The method of claim 14, wherein the oxidant is any of O₂, O₃, H₂O, and an oxygen radical.

17. The method of claim 10, wherein formation of the block film is performed at a temperature in a range from approximately 170° C. to approximately 350° C.

18. A manufacturing method of a semiconductor storage device, the method comprising:
stacking a plurality of material layers of a control gate and a plurality of insulating films above a substrate;
forming a memory hole penetrating through the material layers of the control gate and the insulating films;
depositing a block film, a charge accumulating layer, and a tunnel dielectric film in this order on an inner surface of the memory hole; and
further filling a semiconductor material in the memory hole in order to form a semiconductor pillar, wherein
formation of the block film comprises:
a first stage of forming an aluminum film using an aluminum source containing an amino group or amidinate; and
a second stage of oxidizing the aluminum film with oxygen (O₂).
